(19) United States
(12) Patent Application Publication
(10) Pub. No.: US 2026/0106437 A1
(43) Pub. Date: Apr. 16, 2026

(54) Electrical Box Protection Device

(71) Applicants: Tim Huenink, Livermore, CO (US); Forrest Huenink, Livermore, CO (US)

(72) Inventors: Tim Huenink, Livermore, CO (US); Forrest Huenink, Livermore, CO (US)

(21) Appl. No.: 19/298,797

(22) Filed: Aug. 13, 2025

Related U.S. Application Data
(60) Provisional application No. 63/708,035, filed on Oct. 16, 2024.

(51) Int. Cl. H02G 3/08; H05K 5/02

(52) U.S. Cl. CPC H02G 3/081; H05K 5/0217; H05K 5/0252

(57) ABSTRACT

An electrical box protection device is provided. The device is designed to safeguard nonmetallic sheathed cables and associated electrical boxes from mechanical damage incurred during or after building construction. The device comprises a body formed by a first member and a second member that intersect at an angle, preferably ninety degrees, to create a rigid barrier. The body comprises predrilled holes in symmetric or asymmetric patterns for secure attachment to various framing materials using standard mechanical fasteners. Optional features include a grounding component configured with a grounding lug, tab, or conductive strap and a designated area for ground wire attachment. Additional configurations may comprise a cable guide groove to direct the cable into the electrical box with minimal strain and visual indicators such as compliance markings and orientation symbols to support proper installation.

### CROSS REFERENCE TO RELATED APPLICATION

The present application claims priority to, and the benefit of, U.S. Provisional Application No. 63/708,035, which was filed on Oct. 16, 2024, and is incorporated herein by reference in its entirety.

### FIELD OF THE INVENTION

The present invention relates generally to the field of electrical boxes. More specifically, the present invention relates to an electrical box protection device designed to shield nonmetallic sheathed cables and electrical boxes from mechanical damage during and after construction by serving as a rigid barrier positioned between the box and framing structure. Accordingly, the present disclosure makes specific reference thereto. Nonetheless, it is to be appreciated that aspects of the present invention are also equally applicable to other like applications, devices, and methods of manufacture.

### BACKGROUND

Electrical wiring systems in both residential and commercial construction frequently employ nonmetallic sheathed cables routed into nonmetallic electrical boxes. These boxes are commonly mounted at a height between 40 and 50 inches from the finished floor, a range that corresponds closely with the top edge of standard 48-inch drywall sheets. This alignment introduces a heightened risk that screws, nails, or other fasteners used during drywall installation may inadvertently puncture or compress cables where they enter the boxes. Such accidental damage compromises the mechanical integrity and insulation properties of the cable, increasing the likelihood of shorts, circuit failures, or even fire hazards. This risk is not limited to interior applications; exterior siding installation often involves driving nails into framing near electrical boxes, presenting the same hazards to cable entry points. Existing methods of protecting these entry points are insufficient, often requiring time-intensive modifications or failing to provide adequate physical shielding. Installers and inspectors are left with few reliable options for ensuring code compliance while maintaining an efficient workflow.

Therefore, there exists a long-felt need in the art for an electrical box protection device that prevents physical damage to nonmetallic sheathed cables at the point of entry into electrical boxes during construction activities. There also exists a long-felt need in the art for an electrical box protection device that enables fast and reliable installation without requiring modifications to existing building practices. Moreover, there exists a long-felt need in the art for an electrical box protection device that maintains compliance with National Electrical Code standards while offering optional grounding capabilities.

The subject matter disclosed and claimed herein, in one embodiment thereof, comprises an electrical box protection device. The device is designed to safeguard nonmetallic sheathed cables and associated electrical boxes from mechanical damage incurred during or after building construction. The device comprises a body constructed from galvanized steel, stainless steel, or steel-reinforced polymer composite, formed by a first member and a second member that intersect at an angle, preferably ninety degrees, to create a rigid barrier. The body comprises predrilled holes in symmetric or asymmetric patterns for secure attachment to various framing materials using standard mechanical fasteners. The device may include beveled or rounded edges for safe handling and minimized material interference. Optional features include a grounding component configured with a grounding lug, tab, or conductive strap and a designated area for ground wire attachment. Surface treatments such as plating with zinc, nickel, or tin may also be employed to improve conductivity and corrosion resistance. Additional configurations may comprise a cable guide groove to direct the cable into the electrical box with minimal strain and visual indicators such as compliance markings and orientation symbols to support proper installation. The device may also incorporate an attachment interface that enables direct connection to an electrical box, allowing installation either as an integrated assembly or in separate steps.

In this manner, the electrical box protection device of the present invention accomplishes all the forgoing objectives and provides a device that creates a protective barrier that prevents fasteners from penetrating nonmetallic cables at the entry point into electrical boxes, addressing a known hazard in both interior and exterior construction. The configuration of predrilled mounting holes and optional attachment interfaces permits rapid installation without deviating from standard construction methods. The incorporation of grounding features, cable guide channels, and visual indicators further ensures electrical code compliance, installer safety, and operational reliability. Accordingly, the electrical box protection device offers a comprehensive and practical solution to a longstanding safety and performance issue in the electrical installation industry.

### SUMMARY

The following presents a simplified summary to provide a basic understanding of some aspects of the disclosed innovation. This summary is not an extensive overview, and it is not intended to identify key/critical elements or to delineate the scope thereof. Its sole purpose is to present some general concepts in a simplified form as a prelude to the more detailed description that is presented later.

The subject matter disclosed and claimed herein, in one embodiment thereof, comprises an electrical box protection device. The device is designed to shield electrical boxes and nonmetallic (NM) cables from damage caused by fasteners or objects inserted from the rear of a wall or framing structure. The device is comprised of a body, which includes a first member and a second member forming an angle, preferably 90 degrees. A uniform thickness may be used to meet NEC standards, and the composite option offers reduced weight and electrical non-conductivity. The body is further comprised of one or more predrilled holes, which may vary in placement and diameter. These holes may be arranged in different patterns to allow fastening to various framing materials using standard mechanical fasteners.

During installation, the device is positioned behind an electrical box, with the body serving as a rigid barrier to prevent intrusion by fasteners, thus protecting the electrical box and NM cables. Some embodiments of the body may include beveled or rounded edges to improve handling safety and minimize potential damage to surrounding elements during installation. The device is suitable for use in residential, commercial, and industrial environments, supporting NM cable routing through structural openings while facilitating straightforward and secure installation in both new and retrofit projects.

An additional embodiment may include an attachment interface between the body and the electrical box. This interface may feature slots, tabs, clips, clamps, or threaded holes, allowing either independent or simultaneous mounting of the device and the electrical box as a single unit. Some embodiments may also incorporate a grounding feature comprised of a lug, tab, strap, or combination thereof, establishing electrical continuity between the device and the electrical box. This feature may include a designated ground wire attachment area and plated or coated surfaces to improve conductivity and corrosion resistance.

The invention is also comprised of a method of use involving positioning the device behind the electrical box, fastening it to the framing structure, optionally routing NM cables through the guide channel, securing a ground wire to the grounding area, and using visual indicators to confirm proper installation. A further method of use involves utilizing the attachment interface to affix the body directly to the electrical box, forming an integrated assembly that may be installed onto the framing structure.

Accordingly, the electrical box protection device of the present invention is particularly advantageous as it creates a protective barrier that prevents fasteners from penetrating nonmetallic cables at the entry point into electrical boxes, addressing a known hazard in both interior and exterior construction. The configuration of predrilled mounting holes and optional attachment interfaces permits rapid installation without deviating from standard construction methods. The incorporation of grounding features, cable guide channels, and visual indicators further ensures electrical code compliance, installer safety, and operational reliability. Accordingly, the electrical box protection device offers a comprehensive and practical solution to a longstanding safety and performance issue in the electrical installation industry.

To the accomplishment of the foregoing and related ends, certain illustrative aspects of the disclosed innovation are described herein in connection with the following description and the annexed drawings. These aspects are indicative, however, of but a few of the various ways in which the principles disclosed herein can be employed and are intended to include all such aspects and their equivalents. Other advantages and novel features will become apparent from the following detailed description when considered in conjunction with the drawings.

### BRIEF DESCRIPTION OF THE DRAWINGS

The description refers to provided drawings in which similar reference characters refer to similar parts throughout the different views, and in which:

FIG. 1 illustrates a perspective view of one potential embodiment of an electrical box protection device of the present invention in accordance with the disclosed architecture;

FIG. 2 illustrates a flowchart of a method of using one potential embodiment of an electrical box protection device of the present invention in accordance with the disclosed architecture; and

FIG. 3 illustrates a flowchart of a method of using one potential embodiment of an electrical box protection device of the present invention in accordance with the disclosed architecture.

### DETAILED DESCRIPTION

The innovation is now described with reference to the drawings, wherein like reference numerals are used to refer to like elements throughout. In the following description, for purposes of explanation, numerous specific details are set forth to provide a thorough understanding thereof. It may be evident, however, that the innovation can be practiced without these specific details. In other instances, well-known structures and devices are shown in block diagram form to facilitate a description thereof. Various embodiments are discussed hereinafter. It should be noted that the figures are described only to facilitate the description of the embodiments. They are not intended as an exhaustive description of the invention and do not limit the scope of the invention. Additionally, an illustrated embodiment need not have all the aspects or advantages shown. Thus, in other embodiments, any of the features described herein from different embodiments may be combined.

As noted above, there exists a long-felt need in the art for an electrical box protection device that prevents physical damage to nonmetallic sheathed cables at the point of entry into electrical boxes during construction activities. There also exists a long-felt need in the art for an electrical box protection device that enables fast and reliable installation without requiring modifications to existing building practices. Moreover, there exists a long-felt need in the art for an electrical box protection device that maintains compliance with National Electrical Code standards while offering optional grounding capabilities.

The present invention, in one exemplary embodiment, is comprised of an electrical box protection device. The electrical box protection device functions to protect electrical boxes and nonmetallic cables from potential damage caused by fasteners or other objects inserted from the rear side of a wall or framing structure. The device is comprised of a body that includes a first member and a second member arranged to form an angle, most preferably 90 degrees. To meet NEC standards, the body may be fabricated with a uniform thickness, while the use of composite materials provides advantages such as lower weight and electrical non-conductivity. The body is also comprised of one or more predrilled holes, with variations in their size and placement. The holes may be organized in various configurations to enable attachment to different types of framing materials through standard mechanical fasteners.

Installation of the device involves placing the device directly behind an electrical box, wherein the body acts as a rigid shield to block fasteners and safeguard the electrical box and NM cables. Some versions of the body may feature beveled or rounded edges to enhance installer safety and reduce the risk of damage to adjacent materials. The device is suitable for application in residential, commercial, and industrial settings, facilitating efficient NM cable routing and allowing for quick, secure installation in both new construction and retrofit scenarios.

In an additional embodiment, an attachment interface may be formed between the body and the electrical box. The interface may include features such as but not limited to slots, tabs, clips, clamps, or threaded holes, which permit either separate or combined installation of the device and the electrical box as a unified assembly. Certain embodiments of the device may also feature a grounding mechanism comprised of a lug, tab, strap, or equivalent component, enabling electrical continuity between the device and the electrical box. This mechanism may include a designated area for attaching a ground wire and using plated or coated surfaces to enhance conductivity and resist corrosion.

The invention further includes a method of use that involves positioning the device behind the electrical box, securing it to the framing structure, optionally guiding NM cables through an integrated channel, attaching a ground wire to the designated area, and verifying installation correctness via visual indicators. Another method involves engaging the attachment interface to secure the body directly to the electrical box, forming an integrated unit for simultaneous installation onto a framing structure.

As a result, the electrical box protection device presented herein provides a reliable safeguard against fastener intrusion into nonmetallic cables at their entry point into electrical boxes, effectively mitigating a recognized hazard in both interior and exterior installations. The arrangement of mounting holes and optional attachment mechanisms supports efficient installation within standard building practices. Grounding elements, cable routing channels, and visual markers further ensure adherence to electrical codes, promote safe installation, and support long-term reliability. As a result, the device delivers a practical and comprehensive solution to an enduring challenge in the electrical installation field.

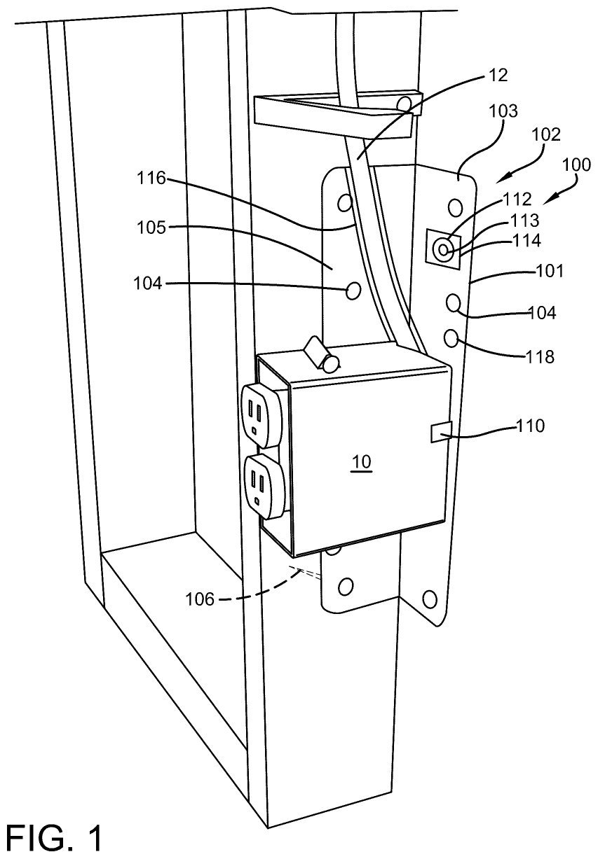

Referring initially to the drawings, FIG. 1 illustrates a perspective view of one potential embodiment of an electrical box protection device 100 of the present invention in accordance with the disclosed architecture. The electrical box protection device 100 is designed to safeguard electrical boxes 10 and nonmetallic (NM) cables 12 (positioned at any height on a wall) from accidental damage caused by hardware, fasteners, or other objects introduced from the rear side of a wall or framing structure.

The device 100 is comprised of a body 102. The body 102 may be comprised of a first member 103 and a second member 105 that forms an angle between 1 and 179 degrees relative to the first member 103, although preferably 90 degrees. The body 102 may be made of materials such as but not limited to different grades of galvanized steel, stainless steel, or steel-reinforced polymer composites, with the specific material selected based on environmental factors such as moisture exposure, chemical exposure, and temperature extremes. In one embodiment, the body 102 may be fabricated with a uniform thickness of approximately 1/16 inch to meet National Electrical Code (NEC) standards for protection of NM cables 12 at entry points into electrical enclosures. The steel-reinforced polymer composite material may provide advantages such as reduced weight and electrical non-conductivity, beneficial for specialized applications.

The body 102 may further include at least one predrilled hole 104, as seen in FIG. 1, which may vary in diameter and placement. In one embodiment the body 102 has a plurality of predrilled holes 104 that may be arranged symmetrically or asymmetrically to accommodate different installation preferences and framing configurations. The arrangement of holes 104 may enable the device 100 to be securely fastened to wood, metal, or composite framing members using standard fastening hardware such as but not limited to wood screws, self-tapping screws, bolts, or equivalent mechanical fasteners.

During installation, the device 100 may be positioned directly behind an electrical box 10, with the body 102 acting as a rigid protective barrier, as seen in FIG. 1. Thus, the body 102 prevents nails, screws, or other fasteners introduced from the opposite side of the wall or framing structure from penetrating the electrical box 10 and/or damaging NM cables 12 entering the electrical box 10 from the rear.

In some embodiments, the body 102 may feature beveled or rounded edges 101, as seen in FIG. 1. The beveled or rounded edges 101 may facilitate safe handling by installers and may prevent potential damage to adjacent materials, cabling, or structural elements during placement and securing of the device 100.

The electrical box protection device 100 may be suitable for residential, commercial, and industrial settings. Typical applications may involve routing NM 12 sheathed cables through walls, ceilings, or floors where protection at the junction with electrical boxes 10 is necessary. The device 100 may allow for rapid and secure installation with minimal alteration to standard construction and electrical installation practices, thereby making it appropriate for both new construction and retrofit scenarios.

In an additional embodiment, the electrical box protection device 100 may further comprise an attachment interface 110 between the body 102 and the electrical box 10, as seen in FIG. 1. The attachment interface 110 may include but is not limited to slots, tabs, clips, clamps, threaded holes, etc. or any combination thereof, enabling the body 102 to be directly affixed to the electrical box 10. This configuration may allow the installer to either mount the electrical box protection device 100 and the electrical box 10 simultaneously as a single integrated assembly or to mount them independently depending on project-specific requirements.

Either embodiment of the electrical box protection device 100 may also include a grounding feature 112 in one embodiment, as seen in FIG. 1. The grounding feature 112 may be comprised of an integrated grounding lug, grounding tab, conductive strap, etc. or any combination thereof, ensuring electrical continuity between the electrical box protection device 100 and the electrical box 10 in metallic system applications. The grounding element 112 may be either fixed or adjustable and may feature a designated area 114 configured for the secure attachment of a ground wire. This configuration may ensure compliance with NEC grounding provisions. In one embodiment, the grounding feature 112 may incorporate plated or coated surfaces 113 with materials such as but not limited to zinc, nickel, or tin to enhance electrical conductivity and to resist corrosion over the operational life of the installation.

In one embodiment, the body 102 may be comprised of an integrated cable guide groove or channel 116. The cable guide groove or channel 116 may assist in directing NM 12 cables smoothly into the electrical box 10, minimizing excessive bending, strain, or mechanical stress that could otherwise compromise cable integrity.

Additionally, the body 102 may be comprised of visual indicators 118, including but not limited to laser-etched compliance markings, directional arrows indicating correct installation orientation, and symbols denoting grounding points. These visual indicators 118 may assist installers and inspectors by providing immediate visual confirmation that the electrical box protection device 100 is properly positioned and that installation complies with relevant safety codes and standards.

The device 100 may also be comprised of at least one fastener 106 to secure the device 100 to a framing member. The fastener 106 may include but is not limited to a nail plate, a spike, a pointed member, a clip, a clamp, etc.

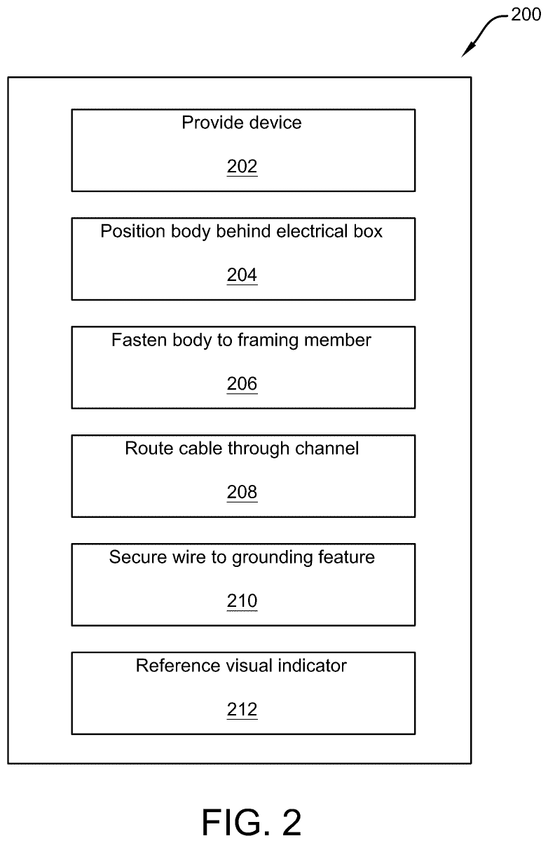

The present invention is also comprised of a method of using 200 the electrical box protection device 100, as seen in FIG. 2. First, an electrical box protection device 100 is provided comprised of a body 102, wherein the body 102 is comprised of at least one first member 103, at least one second member 105, a plurality of predrilled holes 104, beveled or rounded edges 101, an optional grounding feature 112 with a grounding area 114, an optional cable guide groove or channel 116, and optional visual indicators 118 [Step 202]. Then, the body 102 can be positioned directly behind an electrical box 10, wherein the first member 103 and the second member 105 are oriented to provide a protective barrier between the electrical box 10 and a rear framing structure [Step 204]. Next, the body 102 can be fastened to a framing member using mechanical fasteners through the plurality of predrilled holes 104 [Step 206]. Then, an NM cable 12 can be routed through the cable guide groove or channel 116, if present, into the electrical box 10, minimizing strain or mechanical stress [Step 208]. Next, if the grounding feature 112 is present, a ground wire can be secured to the grounding feature 112 to the grounding area 114 to establish electrical continuity between the electrical box protection device 100 and the electrical box 10 [Step 210]. Finally, the visual indicators 118 (if present) can be referenced to confirm correct positioning, orientation, and grounding compliance of the electrical box protection device 100 during or after installation [Step 212].

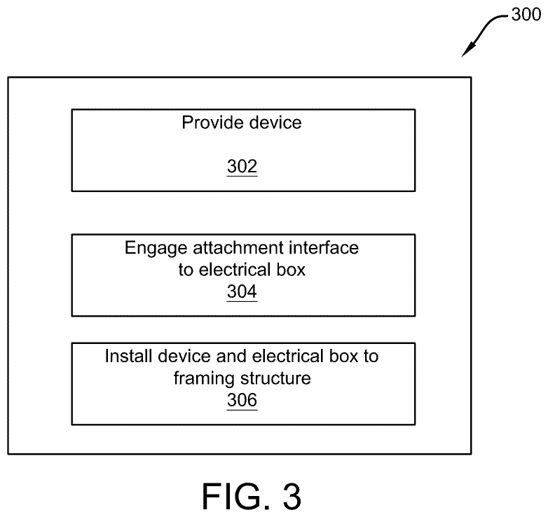

The present invention is further comprised of a method of using 300 the attachment interface 110 of the electrical box protection device 100, as seen in FIG. 3. First, an electrical box protection device 100 is provided comprising an attachment interface 110 formed between the body 102 and an electrical box 10 [Step 302]. Then, the attachment interface 110 can be engaged to directly affix the body 102 to the electrical box 10, forming an integrated assembly [Step 304]. Finally, the integrated assembly comprising the electrical box protection device 100 and the electrical box 10 can be installed together onto a framing structure [Step 306].

Certain terms are used throughout the following description and claims to refer to particular features or components. As one skilled in the art will appreciate, different persons may refer to the same feature or component by different names. This document does not intend to distinguish between components or features that differ in name but not structure or function. As used herein “electrical box protection device” and “device” are interchangeable and refer to the electrical box protection device 100 of the present invention.

Notwithstanding the foregoing, the electrical box protection device 100 of the present invention and its various components can be of any suitable size and configuration as is known in the art without affecting the overall concept of the invention, provided that they accomplish the above-stated objectives. One of ordinary skill in the art will appreciate that the size, configuration, and material of the electrical box protection device 100 as shown in the FIGS. are for illustrative purposes only, and that many other sizes and shapes of the electrical box protection device 100 are well within the scope of the present disclosure. Although the dimensions of the electrical box protection device 100 are important design parameters for user convenience, the electrical box protection device 100 may be of any size, shape, and/or configuration that ensures optimal performance during use and/or that suits the user's needs and/or preferences.

Various modifications and additions can be made to the exemplary embodiments discussed without departing from the scope of the present invention. While the embodiments described above refer to particular features, the scope of this invention also includes embodiments having different combinations of features and embodiments that do not include all the described features. Accordingly, the scope of the present invention is intended to embrace all such alternatives, modifications, and variations as fall within the scope of the claims, together with all equivalents thereof.

What has been described above includes examples of the claimed subject matter. It is, of course, not possible to describe every conceivable combination of components or methodologies for purposes of describing the claimed subject matter, but one of ordinary skill in the art may recognize that many further combinations and permutations of the claimed subject matter are possible. Accordingly, the claimed subject matter is intended to embrace all such alterations, modifications, and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

What is claimed is:

1. An electrical box protection device comprising:
a body comprising:
a first member attached to a second member;
a hole position on the first member or the second member; and
a channel position on the first member or the second member.

2. The electrical box protection device of claim 1, wherein the first member and the second member form and angle between 1 and 179 degrees.

3. The electrical box protection device of claim 1, wherein the first member or the second member is comprised of a beveled edge or a rounded edge.

4. The electrical box protection device of claim 1, wherein the body is comprised of a visual indicator.

5. The electrical box protection device of claim 1, wherein the visual indicator is comprised of a compliance marking or a directional arrow.

6. The electrical box protection device of claim 1, wherein the body is comprised of an attachment interface configured to attach the body to an electrical box.

7. The electrical box protection device of claim 6, wherein the attachment interface is comprised of a slot, a tab, a clip, a clamp, or a threaded hole.

8. The electrical box protection device of claim 1, wherein the body has a uniform thickness of 1/16 in.

9. An electrical box protection device comprising:
a body comprising:
a first member attached to a second member;
a hole position on the first member or the second member; and
a grounding feature.

10. The electrical box protection device of claim 9, wherein the grounding feature is comprised of a grounding lug.

11. The electrical box protection device of claim 9, wherein the grounding feature is positioned within a grounding area of the body.

12. The electrical box protection device of claim 11, wherein the grounding area is composed of a plated surface or a coating surface.

13. The electrical box protection device of claim 12, wherein the plated surface or the coated surface is comprised of a zinc, a nickel, or a tin.

14. The electrical box protection device of claim 9, wherein the first member and the second member form an angle between 1 and 179 degrees.

15. The electrical box protection device of claim 9, wherein the first member or the second member is comprised of a beveled edge or a rounded edge.

16. The electrical box protection device of claim 9, wherein the body is comprised of a visual indicator.

17. The electrical box protection device of claim 9, wherein the body is comprised of an attachment interface configured to attach the body to an electrical box.

18. The electrical box protection device of claim 17, wherein the attachment interface is comprised of a slot, a tab, a clip, a clamp, or a threaded hole.

19. The electrical box protection device of claim 9, wherein the body has a uniform thickness of 1/16 in.

20. A method of using an electrical box protection device, the method comprising the following steps:
providing an electrical box protection device comprised of a body comprising a first member, a second member, and a hole;
positioning the body directly behind an electrical box such that the first member and the second member form a protective barrier between the electrical box and a framing structure; and
fastening the body to a framing member using a mechanical fastener through the hole.
